(19) United States
(12) Patent Application Publication
(10) Pub. No.: US 2026/0122862 A1
(43) Pub. Date: Apr. 30, 2026

(54) COOLING CABINET AND COOLING LOOP

(71) Applicant: LITE-ON TECHNOLOGY CORPORATION, Taipei (TW)

(72) Inventors: Lung-Fu WANG, Taipei (TW); Yung-Chang Chiu, Taipei (TW); Cing-De Wu, Taipei (TW); Pin-Chiao Tseng, Taipei (TW)

(21) Appl. No.: 19/324,181

(22) Filed: Sep. 10, 2025

Related U.S. Application Data
(60) Provisional application No. 63/694,937, filed on Sep. 16, 2024.
(60) Provisional application No. 63/801,941, filed on May 8, 2025.

(30) Foreign Application Priority Data
Aug. 18, 2025 (CN) 202511152151.3

(51) Int. Cl. H05K 7/20

(52) U.S. Cl. CPC H05K 7/20836; H05K 7/20263; H05K 7/20272; H05K 7/20763

(57) ABSTRACT

A cooling cabinet comprises a rack assembly, a power distribution module, a heat exchange module, and a plurality of pump modules. The power distribution module and the heat exchange module are disposed in the rack assembly. The pump modules are detachably mounted in the rack assembly. Each pump module has an inlet and an outlet. The inlet is used to receive coolant flowing through the heat exchange module. Each pump module includes a pump and a temperature sensor. The pump is located adjacent to the inlet and used to drive the coolant to the outlet. The temperature sensor is disposed downstream of the pump and adjacent to the outlet, and is used to detect the temperature of the coolant.

This application claims the benefit of the U.S. provisional application Ser. No. 63/694,937, filed Sep. 16, 2024, the U.S. provisional application Ser. No. 63/801,941, filed May 8, 2025, and CN application No. 202511152151.3, filed Aug. 18, 2025, the disclosures of which are incorporated by reference herein in its entirety.

### TECHNICAL FIELD

The present invention relates to a cooling cabinet and cooling loop for cooling servers.

### BACKGROUND

In order to cool high heat-generating electronic devices (such as servers), it is often necessary to use a water-cooling cabinet to achieve the desired temperature reduction. The cooling cabinet generally includes various functional modules and numerous pipelines. The temperature of the coolant output from the pipelines of the cooling cabinet is a critical parameter of concern in the field. Therefore, temperature sensors are usually installed on the pipelines to monitor the temperature of the coolant.

### SUMMARY

According to one aspect of the present invention, a cooling cabinet is provided, which includes a rack assembly, a power distribution module, a heat exchange module and a plurality of pump modules. The power distribution module is disposed in the rack assembly. The heat exchange module is disposed in the rack assembly. The pump modules are detachably disposed in the rack assembly. Each pump module has an inlet and an outlet. The inlet is used to receive coolant flowing through the heat exchange module. Each pump module includes a pump and a temperature sensor. The pump is located adjacent to the inlet and is used to drive the coolant to the outlet. The temperature sensor is disposed downstream of the pump and adjacent to the outlet, and is used to detect the temperature of the coolant.

Wherein, each pump module further includes an AC-DC converter and a pump controller. The AC-DC converter is electrically connected to the power distribution module and is used to receive an alternating current (AC) from the power distribution module and convert the AC into a direct current (DC). The pump controller is electrically connected to the AC-DC converter and is used to receive the DC from the AC-DC converter and supply the DC to the temperature sensor.

Wherein, in each pump module, the temperature sensor is in communication with the pump controller to transmit a temperature signal of the coolant. The temperature signal is derived from an average temperature of at least two temperature sensors of the pump module.

Wherein, each pump module further includes a pressure sensor. The pressure sensor is disposed downstream of the pump and is used to detect the pressure of the coolant. The pump controller supplies DC to the pressure sensor. The pressure sensor is in communication with the pump controller to transmit a pressure signal of the coolant.

Wherein, each pump module further includes a leakage collection tray and a leakage sensor. The leakage collection tray is disposed below the pump and is used to collect leaked portions of the coolant. The leakage sensor is disposed in the leakage collection tray and is used to detect the coolant collected therein. The pump controller supplies DC to the leakage sensor. The leakage sensor is in communication with the pump controller to transmit a leakage signal of the coolant.

Wherein, the cooling cabinet further comprises a plurality of external sensors. The external sensors are disposed outside the pump modules. Each pump module further includes a sensor hub. The sensor hub is used to receive signals from the external sensors. The pump controller receives DC from the AC-DC converter and supplies the DC to the sensor hub. The sensor hub supplies the DC to the external sensors. The sensor hub is in communication with the pump controller to integrate the signals from the external sensors and transmit the integrated signals to the pump controller.

Wherein, each pump module further includes an inverter. The inverter is electrically connected to the power distribution module and is used to receive AC from the power distribution module and supply the AC to the pump. Each pump module further includes a pump controller. The pump controller is in communication with the inverter and is used to control the inverter to adjust frequency and voltage so as to change a rotational speed of the pump.

Wherein, the power distribution module includes a casing, an AC input connector, a safety protection module, a power branch module, and a plurality of AC output connectors. The power distribution module inputs AC through the AC input connector and outputs AC through at least one AC output connector. The power distribution module converts AC into DC through an AC-DC converter and outputs DC through a DC output connector. The AC input connector is disposed on one side of the casing, and at least one DC output connector is disposed on another side of the casing. The safety protection module is disposed in the casing and electrically connected to the AC input connector. The power branch module is disposed in the casing and electrically connected to the safety protection module, and is used to distribute AC passing through the safety protection module into a plurality of AC power branches. The AC output connectors are disposed on the casing and respectively electrically connected to the power branch module, and are used to output the AC power branches. The AC output connectors are electrically connected to the pump modules in a one-to-one manner to respectively supply the AC power branches to the pump modules.

Wherein, the power distribution module further includes an AC-DC converter, a DC multi-wire terminal, and a power distribution controller. The AC-DC converter is disposed in the casing and electrically connected to the safety protection module, and is used to receive AC from the safety protection module and convert it into DC. The DC multi-wire terminal is electrically connected to the AC-DC converter and is used to receive DC from the AC-DC converter and distribute the DC into a plurality of DC power branches. The power distribution controller is electrically connected to the DC multi-wire terminal and is used to receive one of the DC power branches. The power distribution controller is in serial communication with the pump modules. When one of the pump modules preset as a main communication node fails, the power distribution controller switches to another pump module as a new main communication node.

Wherein, the heat exchange module includes a heat exchanger and a proportional valve. The heat exchanger is connected to the pump modules and is used to perform heat exchange on the coolant by means of a heat exchange fluid. The proportional valve is electrically connected to the power distribution controller and is used to adjust its valve opening to regulate the flow rate of the heat exchange fluid.

Wherein, when an average temperature value of part of the temperature sensors exceeds a first threshold, the proportional valve increases its valve opening to increase the flow of the heat exchange fluid. When the average temperature value of part of the temperature sensors is below another threshold, the proportional valve decreases its valve opening to reduce the flow of the heat exchange fluid.

Wherein, the heat exchange module includes a filling reservoir and a filling pump. The filling reservoir is disposed in the rack assembly. The filling pump is connected to the filling reservoir and electrically connected to the power distribution controller, and is used to drive the coolant from the filling reservoir when the amount of coolant entering the pump modules is insufficient. The heat exchange module further includes a solenoid valve. The solenoid valve is electrically connected to the power distribution controller and is used to guide a portion of the coolant flowing out of the outlets of the pump modules toward the filling reservoir.

According to another aspect of the present invention, a cooling loop is provided for supplying coolant to an electronic device for cooling. The cooling loop comprises a secondary loop piping, a heat exchange module, and a plurality of pump modules. The secondary loop piping has a secondary-loop supply port and a secondary-loop return port. The secondary-loop supply port is used to output coolant to the electronic device, and the secondary-loop return port is used to receive the coolant from the electronic device. The heat exchange module is disposed between the secondary-loop supply port and the secondary-loop return port, and provides heat exchange between the secondary loop piping and a primary loop piping. The pump modules are disposed between the heat exchange module and the secondary-loop supply port, and are arranged in parallel. Each pump module has an inlet and an outlet, the inlet is used to receive coolant flowing through the heat exchange module. Each pump module includes a pump and a temperature sensor. The pump is located adjacent to the inlet and is used to drive the coolant to the outlet. The temperature sensor is disposed between the pump and the outlet and is used to detect the temperature of the coolant.

Wherein, each pump module further includes a pump controller. The temperature sensor is in communication with the pump controller to transmit a temperature signal of the coolant. The temperature signal is an average temperature of the temperature sensors.

Wherein, a proportional valve is disposed on the primary loop piping. The valve opening of the proportional valve is controlled according to the average temperature to control the flow of the primary loop piping.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A and FIG. 1B illustrate perspective views of a cooling cabinet according to an embodiment of the present invention from different viewing angles.

FIG. 2 illustrates a pipeline block diagram of the cooling cabinet according to an embodiment of the present invention.

FIG. 3A illustrates a perspective view of a pump module included in the cooling cabinet shown in FIGS. 1A and 1B.

FIG. 3B illustrates a partial detail view of the pump module shown in FIG. 3A.

FIG. 3C illustrates a top view of the pump module shown in FIG. 3A.

FIGS. 3D and 3E illustrate functional block diagrams about the pump module.

FIG. 4A illustrates a perspective view of a power distribution module included in the cooling cabinet shown in FIGS. 1A and 1B.

FIG. 4B illustrates a functional block diagram about the power distribution module.

FIG. 5 illustrates a detailed view of a heat exchange module of the cooling cabinet shown in FIGS. 1A and 1B.

FIG. 6 illustrates a detailed view of a liquid quality monitoring module of the cooling cabinet shown in FIGS. 1A and 1B.

FIG. 7 illustrates a schematic view of a filling pump and components interacting therewith included in the cooling cabinet shown in FIGS. 1A and 1B.

### DETAILED DESCRIPTION

Detailed descriptions of the embodiments of the specification are disclosed below with reference to the accompanying drawings. Apart from the detailed descriptions provided, any embodiments in which the present invention can be used as well as any substitutions, modifications or equivalent changes of the said embodiments are within the scope of the disclosure, and the descriptions and definitions in the claims shall prevail. In the following detailed description, for purposes of explanation, numerous specific details are set forth in order to provide a thorough understanding of the disclosed embodiments. It will be apparent, however, that one or more embodiments may be practiced without these specific details. Additionally, well-known common steps or components are not described in detail to avoid unnecessarily limiting the present invention. The same or similar elements in the figures are represented by the same or similar symbols.

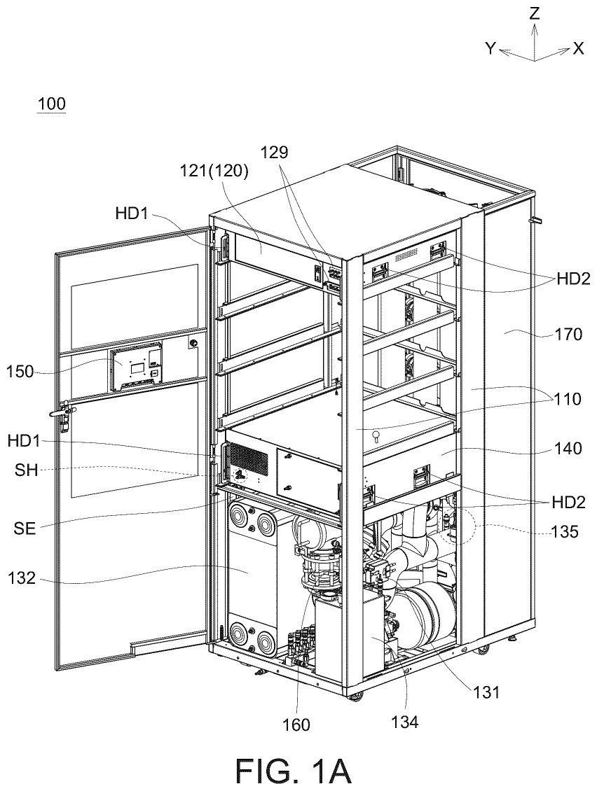

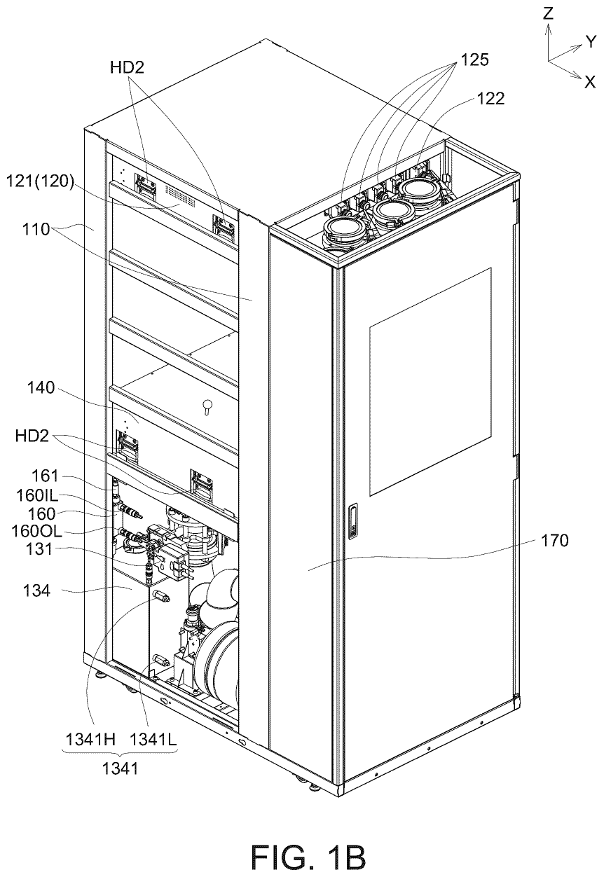

Please refer to FIGS. 1A, 1B, and 2. FIGS. 1A and 1B illustrate perspective views of a cooling cabinet 100 according to an embodiment of the present invention from different viewing angles, while FIG. 2 is a schematic block diagram illustrating the pipeline layout of the cooling cabinet 100.

The cooling cabinet 100 can be used for cooling an electronic device (not shown), such as a server, e.g., a cloud server, an artificial intelligence server, a big-data server, or other types of high-power or high-heat-generating electronic devices. The cooling cabinet 100 includes a rack assembly 110, a power distribution module 120, a heat exchange module 130, a plurality of pump modules 140, a human-machine interface 150, a liquid quality monitoring module 160, and a manifold module 170. The rack assembly 110 is a cabinet frame. The power distribution module 120, the heat exchange module 130, the pump modules 140 and the liquid quality monitoring module 160 are installed inside the rack assembly 110. The human-machine interface 150 is disposed outside the power distribution module 120 and the pump modules 140 and is pivotally connected to the rack assembly 110, so that a user may turn it on and learn the operating status of the cooling cabinet 100. The manifold module 170 is disposed at the rear side of the rack assembly 110, i.e., on the opposite side where the human-machine interface 150 is located.

In FIGS. 1A and 1B, for clarity, only a single pump module 140 is illustrated for explanation. However, it should be understood that the present invention may be provided with multiple pump modules 140 (e.g., four). These pump modules 140 may be vertically stacked (parallel to the Z-axis) in the central region of the rack assembly 110, for example, positioned longitudinally between the power distribution module 120 and the heat exchange module 130. The pump module 140 is detachably mounted to the rack assembly 110. For example, the pump module 140 may be slid along the −X axis and removed from the rack assembly 110 by pulling the handles HD1 located on both sides thereof. However, when the pump module 140 is removed from the rack assembly 110 and carried, lifting the pump module 140 solely by the handles HD1 may cause damage to the handles HD1. Therefore, an additional handle HD2 is provided at the side of the pump module 140 to assist in moving the pump module 140. Similarly, the power distribution module 120 is also detachably mounted to the rack assembly 110. For example, the power distribution module 120 may be slid along the −X axis and removed from the rack assembly 110 by pulling the handle HD1. Handles HD2 are also provided on both sides of the power distribution module 120 to assist in moving the power distribution module 120 after detachment, thereby preventing damage to the handles HD1. Since the pump modules 140 and the power distribution module 120 are relatively prone to failure and require maintenance, while the heat exchanger 132 (e.g., a plate heat exchanger) of the heat exchange module 130 is less likely to be damaged and is difficult to move due to its weight, the pump modules 140 and the power distribution module 120 are disposed in the upper half of the cooling cabinet 100 to facilitate removal and maintenance. The heat exchanger 132 is disposed in the lower half of the cooling cabinet 100, thereby improving maintenance efficiency and the rationality of the cabinet design.

As shown in FIG. 2, the pump modules 140 are disposed on the piping of a secondary loop. The heat exchanger 132 in the heat exchange module 130 is connected to the pump modules 140 on the secondary loop. The piping of a primary loop and the piping of the secondary loop exchange heat energy within the heat exchanger 132 of the heat exchange module 130, but the coolant in the piping does not mix. That is, in FIG. 2, the left side of the heat exchanger 132 corresponds to the primary loop piping, while the right side corresponds to the secondary loop piping. In this embodiment, the secondary loop piping is used for cooling the electronic device (not shown). The coolant is delivered to the electronic device along a secondary-loop supply direction, i.e., the invention provides a cooling loop for supplying coolant to the electronic device for cooling purposes. After cooling the electronic device, the coolant flowing back along a secondary-loop return direction sequentially passes through a pressure sensor P2R, a temperature sensor T2R, a drain valve DV, the liquid quality monitoring module 160, a filling reservoir 134 and a filling pump 135 included in the heat exchange module 130. The coolant enters the heat exchanger 132 to perform heat exchange with the primary loop piping. After completing heat exchange, the coolant sequentially flows through a flow meter F2 and an expansion vessel EV, and is then distributed to each pump module 140. The pump modules 140 provide circulation power, so that the coolant again flows toward the electronic device for cooling operation, thereby forming the main loop of the secondary loop. In addition, the manifolds of the secondary-loop supply direction and return direction are disposed in the manifold module 170.

The pressure sensor P2R and the temperature sensor T2R can detect the pressure and temperature of the coolant returning in the secondary loop piping. The drain valve DV may selectively discharge the returning coolant flowing therethrough to perform over-pressure relief. The flow meter F2 is used to detect the flow rate of the coolant returning in the secondary loop piping (e.g., in LPM, liters per minute). For example, the flow rate of the coolant driven by a single pump module 140 may range from 50 to 500 LPM. In one embodiment, three pump modules 140 may be used to operate simultaneously, while another pump module 140 remains in standby mode, so that the total coolant flow rate in the entire secondary loop piping ranges from 150 to 1500 LPM. The pump modules 140 are arranged in parallel. The expansion vessel EV is used to regulate and stabilize the pressure within the secondary loop piping.

The primary loop piping is used to carry away heat energy from the coolant of the secondary loop piping. As shown in FIG. 2, a proportional valve 131 and the heat exchanger 132 included in the heat exchange module 130 are disposed on the primary loop piping. A heat exchange fluid (e.g., water) supplied from external infrastructure (e.g., a cooling tower) of the cooling cabinet 100 sequentially flows through a pressure sensor P1S, a temperature sensor T1S, and another pressure sensor P1Sb, and then enters the heat exchanger 132 to perform heat exchange with the secondary loop piping so as to carry away heat energy. After the heat exchange, the heat exchange fluid sequentially flows through a flow meter F1, a temperature sensor T1R, a pressure sensor P1R, and the proportional valve 131, and finally returns to the infrastructure/supply source or is discharged elsewhere, thereby forming the primary loop.

The pressure sensors P1S and P1Sb and the temperature sensor T1S can detect the pressure and temperature of the heat exchange fluid supplied in the primary loop piping. The heat exchanger 132 may conduct heat exchange between the coolant in the secondary loop piping and the heat exchange fluid. The flow meter F1 may detect the flow rate (e.g., in LPM) of the heat exchange fluid after flowing through the heat exchanger 132. The pressure sensor P1R and the temperature sensor T1R may detect the pressure and temperature of the heat exchange fluid returning in the primary loop piping. The proportional valve 131 may be used to adjust the flow rate of the heat exchange fluid. For example, when the thermal load on the secondary loop piping is high, resulting in a higher temperature of the coolant on the secondary loop, the proportional valve 131 can be controlled to increase the valve opening, thereby accelerating the return flow of the heat exchange fluid of the primary loop, and thus increasing the flow rate of the heat exchange fluid supplied by the infrastructure/supply source. Conversely, when the thermal load of the secondary loop piping is low, resulting in a lower temperature of the coolant of the secondary loop, the proportional valve 131 can be controlled to reduce the valve opening, thereby increasing the flow resistance of the returning heat exchange fluid on the primary loop, and thus reducing the supply flow rate of the heat exchange fluid from the infrastructure/supply source.

As shown in FIG. 2, the cooling loop provided by the present invention may include the secondary loop piping, the heat exchange module 130, and a plurality of pump modules 140. The secondary loop piping has a secondary-loop supply port and a secondary-loop return port. The secondary-loop supply port may be used to output the coolant to an electronic device outside the cooling cabinet, while the secondary-loop return port may be used to receive the coolant from the electronic device. The heat exchange module 130 is disposed between the secondary-loop supply port and the secondary-loop return port and conducts heat exchange between the secondary loop piping and the primary loop piping. The plurality of pump modules 140 are disposed between the heat exchange module 130 and the secondary-loop supply port. The plurality of pump modules 140 may be arranged in parallel.

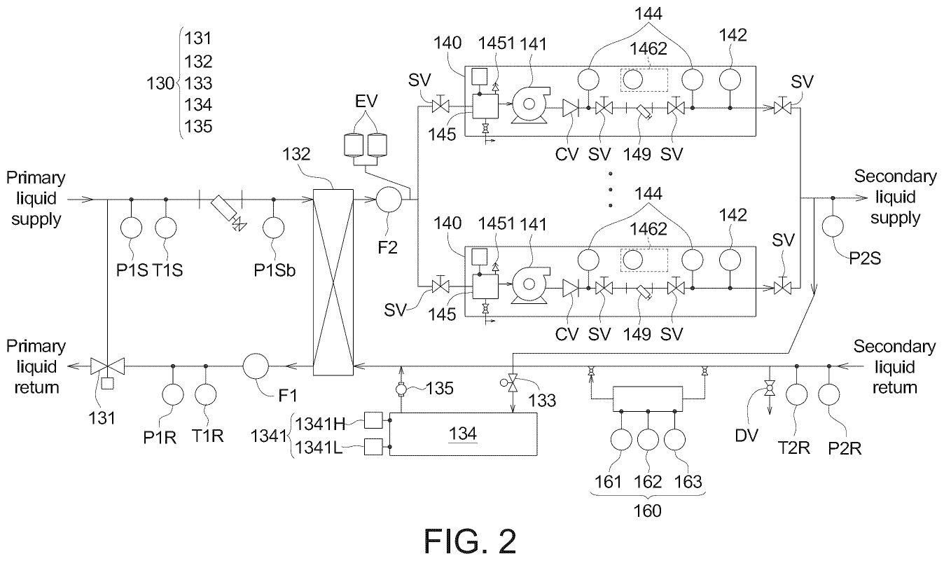

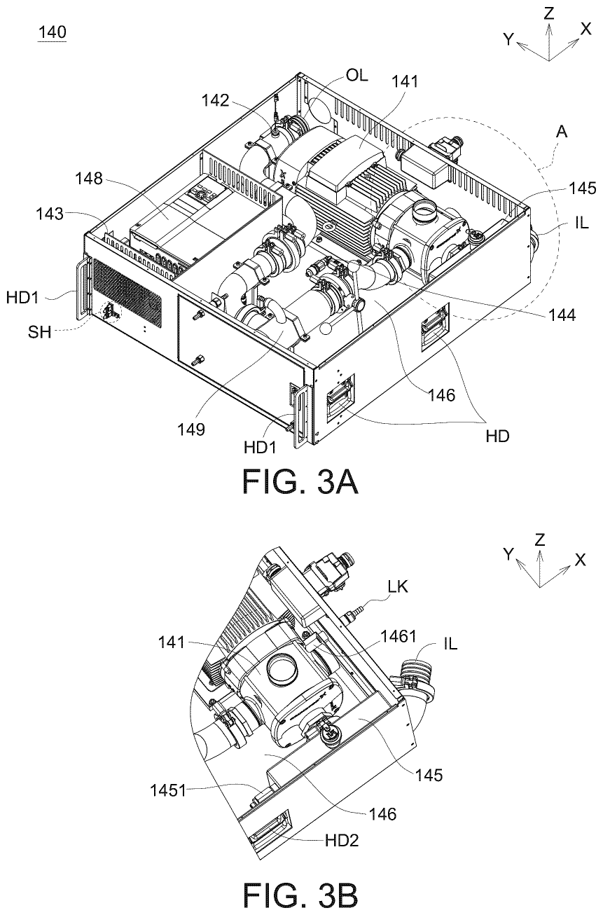

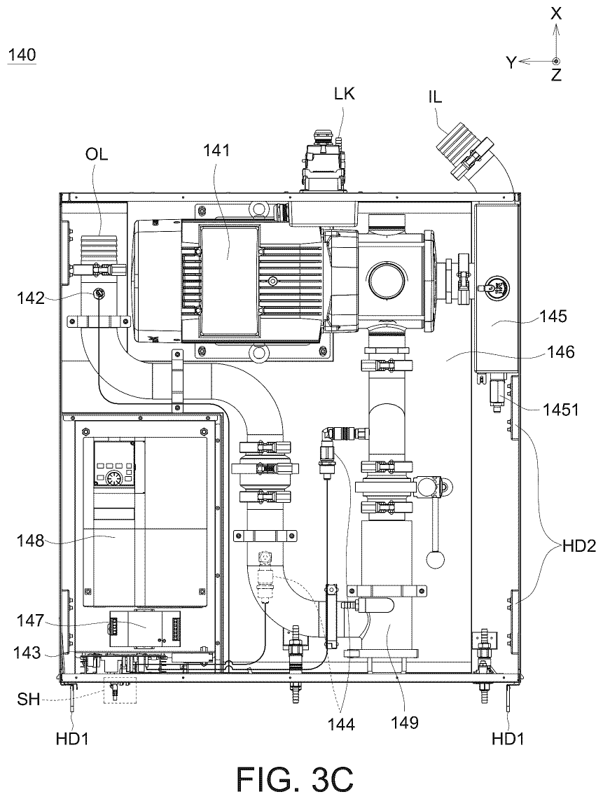

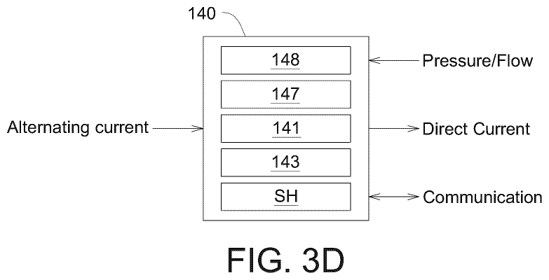

Please also refer to FIGS. 3A, 3B, 3C, 3D, and 3E. FIG. 3A illustrates a perspective view of the pump module 140. FIG. 3B illustrates a detailed view of a partial region A of the pump module 140 in FIG. 3A. FIG. 3C illustrates a top view of the pump module 140 in FIG. 3A, while FIGS. 3D and 3E illustrate functional block diagrams of the pump module 140.

The pump module 140 is used to drive the coolant in the secondary loop piping and the coolant is circulated to the electronic device so as to absorb the heat energy generated thereby. The pump module 140 has an inlet IL and an outlet OL, and includes a pump 141, a temperature sensor 142, a pump controller 143, a pressure sensor 144, a reservoir 145, a level sensor 1451, a leakage collection tray 146, a leak sensor 1462 (shown in FIG. 2), an AC-DC converter 147, an inverter 148, a filter 149, and a sensor hub SH. That is, compared to conventional cooling cabinets which include only a single temperature sensor at the terminal cooling path supplied to the server, each of the plurality of pump modules 140 of the present invention is provided with a temperature sensor 142 therein. Therefore, even if one temperature sensor 142 fails, the cooling cabinet 100 still retains temperature sensors 142 in other pump modules 140 as backups, allowing continued monitoring and control of the coolant temperature.

The inlet IL is used to receive the coolant flowing through the heat exchange module 130. That is, after completing heat exchange, the coolant may enter the pump module 140 through the inlet IL, and is then circulated by the pump 141. Inside the pump module 140 or on the upstream and downstream secondary loop piping thereof, a shutoff valve SV (shown in FIG. 2) may optionally be disposed. The shutoff valve SV may selectively cut off or connect the flow of the coolant according to operational needs, so as to facilitate maintenance or system regulation. On the downstream secondary loop piping of the pump 141 in the pump module 140, a check valve CV (shown in FIG. 2) may optionally be disposed. The check valve CV may prevent backflow of the coolant in the piping, thereby ensuring unidirectionality of the coolant flow and preventing return flow caused by pressure variations when the pump 141 stops operating. The pump 141 is disposed adjacent to the inlet IL and is used to drive the coolant to flow through the internal pipeline to the outlet OL. The coolant then passes through the pressure sensor P2S and is supplied to the electronic device. The temperature sensor 142 is disposed downstream of the pump 141 and is located adjacent to the outlet OL, and is used to detect the temperature of the coolant flowing in the internal pipeline of the pump module 140. The pressure sensor 144 is disposed downstream of the pump 141 and is used to detect the pressure of the coolant flowing through the internal pipeline of the pump module 140. The reservoir 145 is disposed upstream of the pump 141 and is used to store the coolant entering from the inlet IL. The level sensor 1451 is disposed in the reservoir 145 and is used to detect the liquid level of the coolant inside the reservoir 145.

The leakage collection tray 146 is disposed below the pump 141 and located beneath the internal pipeline of the pump module 140. When the internal pipeline of the pump module 140 is in operation, the coolant may leak from various connection points. The leakage collection tray 146 can be used to collect the leaked portion of the coolant. As shown in FIG. 3B, the leakage collection tray 146 has a leakage concentration area 1461, which is recessed and formed in the leakage collection tray 146. The leakage concentration area 1461 is connected to a leakage outlet LK. The coolant leakage collected by the leakage collection tray 146 can be discharged to the outside via the leakage outlet LK. A leakage sensor 1462 may be disposed in the leakage collection tray 146 and is configured to detect the coolant inside the leakage collection tray 146. For example, when the coolant leakage level exceeds a threshold, or when the liquid level in the leakage concentration area 1461 is higher than the leakage outlet LK, the coolant can be discharged through the leakage outlet LK to an external manifold (not shown). A filter 149 is disposed downstream of the pump 141 and is used to filter impurities from the coolant driven by the pump 141.

As shown in FIG. 3D, the pump module 140 may perform AC-DC conversion and output DC power, receive pressure and flow signals from external sensors, communicate with the power distribution module and external sensors, and receive AC power for output to the pump. The above functions mainly involve the inverter 148, the AC-DC converter 147, the pump 141, the pump controller 143, and the sensor hub SH, as described below.

The power distribution module 120 may provide an AC power (e.g., between 380 to 500 volts) to each pump module 140. The AC-DC converter 147 and the inverter 148 in each pump module 140 are electrically connected to the power distribution module 120, while the pump controller 143 is electrically connected to the AC-DC converter 147. As shown in FIG. 3E, the AC power output from the power distribution module 120 is supplied to the inverter 148. The inverter 148 is used to receive AC power from the power distribution module 120 and supply the AC power to the pump 141, thereby driving the pump 141. The AC power output from the power distribution module 120 is also supplied to the AC-DC converter 147, which is used to receive AC power from the power distribution module 120, convert it into DC power (e.g., 48 volts), and output the DC power to the pump controller 143. As shown in FIG. 3E, the pump controller 143 is in communication with (e.g., but not limited to Modbus communication) the inverter 148. Accordingly, the pump controller 143 can control the inverter 148 to adjust frequency and voltage, thereby changing the rotation speed of the pump 141.

The pump controller 143 receives DC power from the AC-DC converter 147 and may further adjust the voltage (e.g., but not limited to stepping down from 48 volts to 24 volts), and then supply the DC power via power lines to the temperature sensor 142, the pressure sensor 144, the level sensor 1451, the leakage sensor 1462, and the sensor hub SH, so that the sensors or hub inside the pump module 140 can operate properly. Within each pump module 140, the internal sensors such as the temperature sensor 142, the pressure sensor 144, the level sensor 1451, and the leakage sensor 1462 are all in communication with the pump controller 143, so as to transmit sensed signals of coolant temperature, pressure, level, and leakage to the pump controller 143. For example, as shown in FIG. 3E, the temperature, pressure, level, and leakage signals detected by the internal sensors of the pump module 140 may be transmitted to the pump controller 143 through analog signals. The pump controller 143 monitors the sensed signals from the pressure sensor 144, the level sensor 1451, and the leakage sensor 1462, and monitors the operation of the cooling cabinet 100 based on the sensed signal from the temperature sensor 142.

It should be noted that the present invention achieves simplification by arranging the temperature sensor 142 at the outlet OL and electrically connecting the temperature sensor 142 to the pump controller 143. This invention allows the system to omit part of the wiring originally required to connect the pump controller 143 with external sensors of the pump module 140, effectively reducing the quantity and length of power lines, and further simplifying the cabinet's circuit and piping configuration. In addition, by modularizing the power distribution system, the pump system, and the manifold, and placing the modules across different areas of the cabinet, the present invention significantly enhances system integration, wiring flexibility, and safety while also facilitating subsequent maintenance operations.

As shown in FIG. 3E, the sensor hub SH is electrically connected to external sensors ES, which are disposed outside the pump module 140. The external sensors ES may include, for example, the flow meter F2, the pressure sensor P2S and the pressure sensor P2R. The sensor hub SH is used to supply DC power (e.g., 24 volts) to the external sensors ES, allowing them to operate properly. The sensor hub SH is in communication with (e.g., but not limited to CANbus communication) the pump controller 143. The sensor hub SH is used to receive signals from the external sensors ES, integrate the signals, and transmit them to the pump controller 143. For example, the coolant flow and pressure signals detected by the flow meter F2, the pressure sensor P2S, and the pressure sensor P2R may be transmitted (e.g., but not limited to Modbus communication) to the sensor hub SH, and then further transmitted from the sensor hub SH to the pump controller 143, such as in analog signal form. The pump controller 143 may monitor the operation of the cooling cabinet 100 based on the sensed signals from the external sensors ES.

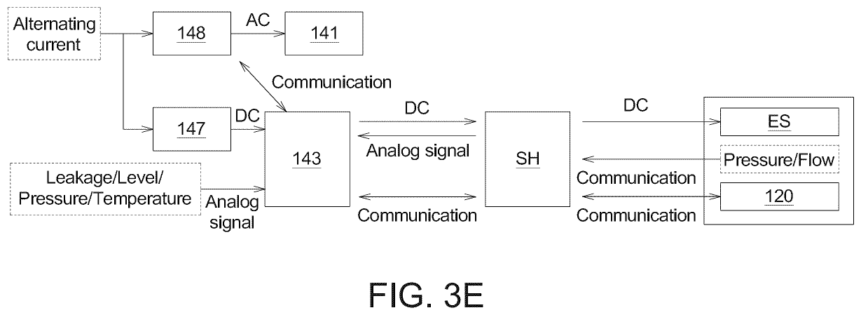

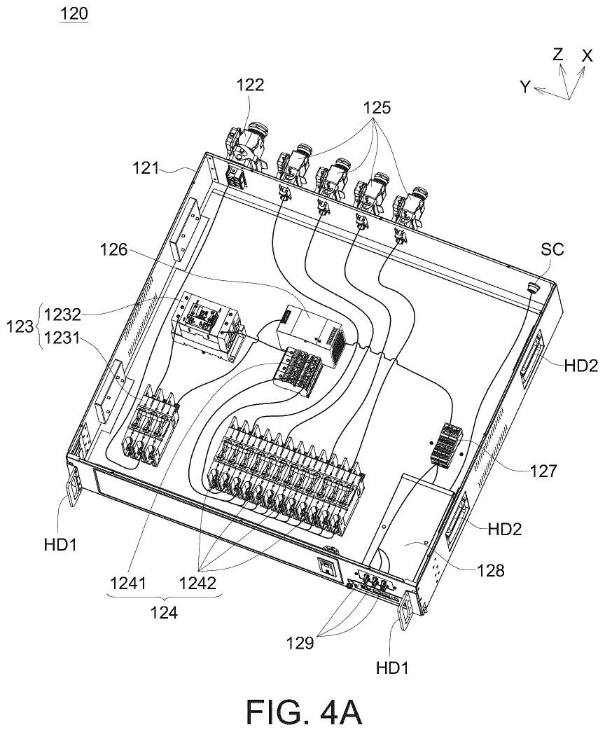

Please also refer to FIGS. 4A and 4B, wherein FIG. 4A illustrates a perspective view of the power distribution module 120, and FIG. 4B illustrates a functional block diagram of the power distribution module 120.

The power distribution module 120 includes a casing 121, an AC input connector 122, a safety protection module 123, a power branch module 124, multiple AC output connectors 125, an AC-DC converter 126, a DC multi-wire terminal 127, a power distribution controller 128, and multiple DC output connectors 129. The AC input connector 122, the AC output connectors 125, and the DC output connectors 129 are disposed on the casing 121. The AC input connector 122 and the AC output connectors 125 are arranged on the same side of the casing 121, while the DC output connectors 129 are arranged on the opposite side of the casing 121. That is, the DC output connectors 129 are disposed on a side opposite to the AC input connector 122 and the AC output connectors 125. Referring to FIGS. 1A and 1B, the DC output connectors 129 are disposed on the side adjacent to the human-machine interface 150 (i.e., arranged on the front side of the rack assembly 110), while the AC input connector 122 and the AC output connectors 125 are disposed on the side opposite the human-machine interface 150 (i.e., arranged on the rear side of the rack assembly 110). Since AC input/output connectors are usually larger in size, this configuration can avoid interference with the opening of the rack door equipped with the human-machine interface, thereby improving maintenance efficiency and achieving a rational mechanical configuration. It also prevents the user from contacting AC power hazards. In addition, separating the AC input/output connectors and the DC output connectors on opposite sides of the casing helps reduce the risk of interference between wires of different voltage levels, further enhancing user safety and maintenance convenience.

The safety protection module 123, the power branch module 124, the AC-DC converter 126, the DC multi-wire terminal 127, and the power distribution controller 128 are disposed inside the casing 121. The safety protection module 123 includes a first breaker 1231 and a contactor 1232. The power branch module 124 includes an AC multi-wire terminal 1241 and multiple second breakers 1242. The AC input connector 122 is used to receive a main power supply (not shown) from outside the cooling cabinet 100. The main power supply may be an AC power source (e.g., between 380 to 500 volts). As shown in FIG. 4A, the first breaker 1231 of the safety protection module 123 is connected via a power line to the AC input connector 122, and then connected via a power line to the contactor 1232 of the safety protection module 123. The contactor 1232 is connected via a power line to the AC multi-wire terminal 1241 of the power branch module 124. The AC multi-wire terminal 1241 is further electrically connected via multiple power lines to multiple second breakers 1242 of the power branch module 124. These second breakers 1242 are each electrically connected via power lines to multiple AC output connectors 125 in a one-to-one manner. In addition, the first breaker 1231 of the safety protection module 123 is connected via another power line to the AC-DC converter 126, which is connected via a power line to the DC multi-wire terminal 127. The DC multi-wire terminal 127 is further connected via multiple power lines to the power distribution controller 128 and the multiple DC output connectors 129.

The first breaker 1231 may be configured for a load with a rated power of approximately 26.4 kW. The second breakers 1242 may be configured for a load with a rated power of approximately 6.4 kW. The contactor 1232 may be used to switch circuits corresponding to a load of about 26.4 kW. The contactor 1232 receives DC power supplied by the AC-DC converter 126 via the DC multi-wire terminal 127, so that the contactor 1232 can operate properly. As shown in FIG. 4B, the contactor 1232 may be electrically connected to the emergency switch button SB of the cooling cabinet 100. The emergency switch button SB may be disposed, for example, on the human-machine interface 150 for user operation, i.e., the human-machine interface 150 is electrically connected to the contactor 1232.

When an emergency event occurs that requires shutdown of the cooling cabinet 100, the user can press the emergency switch button SB to trigger the contactor 1232, so that the contactor 1232 disconnects the circuit between the first breaker 1231 and the AC multi-wire terminal 1241. When the emergency event is resolved and the cooling cabinet 100 needs to be restarted, the user can operate the human-machine interface 150 to reconnect the circuit between the contactor 1232, the first breaker 1231 and the AC multi-wire terminal 1241.

As shown in FIG. 4B, the AC power provided by the main power supply outside the cooling cabinet 100 sequentially passes through the AC input connector 122, the first breaker 1231, the contactor 1232, the AC multi-wire terminal 1241 and the second breakers 1242, and is then output to each pump module 140. This path constitutes an AC circuit to supply AC power to the pump modules 140, allowing the pump modules 140 to operate properly. The power branch module 124 (including the AC multi-wire terminal 1241 and the multiple second breakers 1242) is used to distribute the AC power passing through the safety protection module 123 (including the first breaker 1231 and the contactor 1232) into multiple AC power branches. The AC output connectors 125 are electrically connected to the pump modules 140 in a one-to-one manner to supply each AC power branch to each pump module 140. The AC output connectors 125 are used to output these AC power branches to the respective pump modules 140.

The AC-DC converter 126 is used to receive AC power from the first circuit breaker 1231 and convert it into DC power. As shown in FIG. 4B, the AC power supplied by the main power source outside the cooling cabinet 100 sequentially passes through the AC input connector 122 and the first circuit breaker 1231 and then enters the AC-DC converter 126 for conversion. The converted DC power is then output to the power distribution controller 128 via the DC multi-terminal 127, thereby forming a DC power path. The DC multi-terminal 127 receives DC power from the AC-DC converter 126 and distributes it into multiple DC power branches. The power distribution controller 128 receives one of these DC power branches. For example, the power distribution controller 128 can be electrically connected to the proportional valve 131 and solenoid valve 133 included in the heat exchange module 130, so as to supply DC power to the proportional valve 131 and solenoid valve 133, thereby enabling their normal operation. Multiple DC output connectors 129 are respectively and electrically connected to the DC multi-terminal 127 and are used to output some of the DC power branches to the exterior of the power distribution module 120. For instance, the DC multi-terminal 127 can be electrically connected to the filling pump 135 and supply DC power to the filling pump 135 via the DC output connector 129, thereby enabling normal operation of the filling pump 135.

The cooling cabinet 100 may further include a sensor extension board SE. The sensor extension board SE is in communication with the power distribution controller 128 to centrally integrate signals from the liquid quality monitoring module 160 and other sensors OS located outside the pump modules 140, and transmit these signals to the power distribution controller 128 for monitoring. The liquid quality monitoring module 160 includes a pH sensor 161, a conductivity sensor 162 and a turbidity sensor 163. The other sensors OS may include, for example, a flow meter F1, a level sensor 1341, temperature sensors T1S, T1R, T2R, pressure sensors P1S, P1R, and/or the leakage sensors (not shown) selectively installed on the secondary loop piping. The power distribution controller 128 can communicate with multiple pump modules 140 (e.g., via CAN bus). The power distribution controller 128 connects to the signal connector SC of the power distribution module 120 (shown in FIG. 4A) through a signal line, while the pump controllers 143 of the multiple pump modules 140 can be connected to the signal connector SC to establish communication between the power distribution module 120 and the pump modules 140. For example, the power distribution controller 128 can communicate with the pump controllers 143 within each pump module 140 in a daisy-chain configuration. Any one of the pump modules 140 can be designated as the main communication node to serve as the initial communication endpoint with the power distribution controller 128. If the designed main communication node fails or becomes unable to communicate properly, the power distribution controller 128 can automatically switch to another pump controller 143 of another pump module 140 as the new main communication node, thereby maintaining communication availability and enhancing overall system reliability and stability.

The power distribution controller 128 can, for example, control the proportional valve 131, solenoid valve 133 and filling pump 135 via analog signal transmission. The power distribution controller 128 can control the proportional valve 131 to adjust its valve opening and regulate the flow of the heat exchange fluid. For example, when three pump modules 140 are operating simultaneously and another pump module 140 is in standby mode, the average temperature measured by the temperature sensors 142 of the three operating pump modules 140 is regarded as the coolant temperature. When the average temperature exceeds a threshold, the power distribution controller 128 can control the proportional valve 131 to increase its valve opening, thereby increasing the flow rate of the heat exchange fluid in the primary loop. Conversely, when the average temperature measured by the temperature sensors 142 of the three pump modules 140 falls below another threshold value, the power distribution controller 128 can reduce the valve opening of the proportional valve 131, lowering the flow of heat exchange fluid in the primary loop, thus achieving temperature control of the coolant. In addition, the human-machine interface 150 is in communication with the power distribution controller 128 (e.g., via Modbus) to allow the user to monitor the operational status of the power distribution module 120. The calculation of average temperature is not limited to three temperature sensors 142; it may involve two or more sensors.

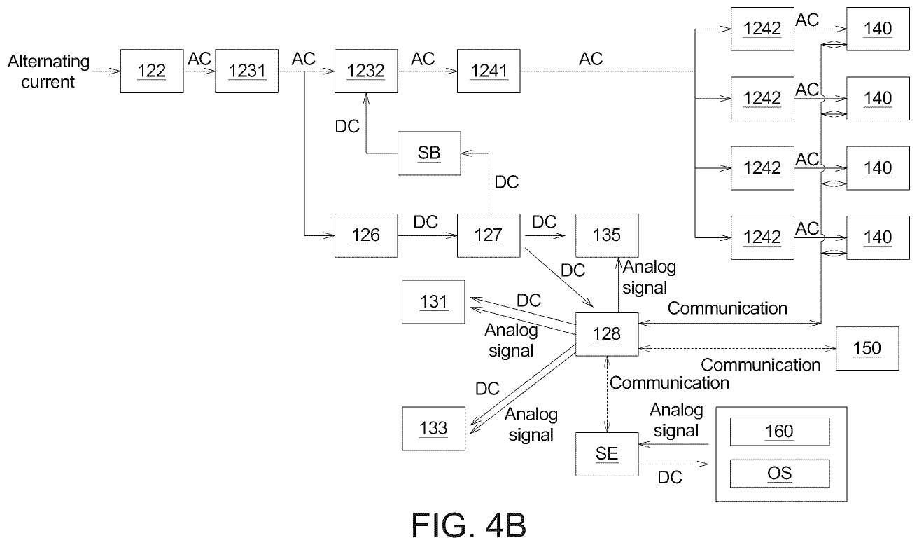

Please further refer to FIG. 5. FIG. 5 illustrates a detailed view of the heat exchange module 130 of the cooling cabinet 100, intended to show the configuration and operation of the level sensor 1341.

The heat exchange module 130 includes a level sensor 1341 installed in the filling reservoir 134 to detect the coolant level in the filling reservoir 134. The level sensor 1341 may include a high-level sensor 1341H and a low-level sensor 1341L wherein both sensors are electrically connected to the power distribution controller 128 of the power distribution module 120. When the coolant level in the filling reservoir 134 reaches a first predetermined liquid level threshold (e.g., 20% of filling capacity), the low-level sensor 1341L transmits the corresponding signal to the power distribution controller 128. In response, the power distribution controller 128 suspends the operation of the refill pump 135 to prevent the pump from drawing in air, which could result in damage. When the coolant level reaches a preset second liquid level threshold (e.g., 80% of filling capacity), the high-level sensor 1341H transmits a corresponding signal to the power distribution controller 128. In response, the power distribution controller 128 controls the human-machine interface to issue a warning signal, prompting the user to perform a drainage operation to prevent overfilling of the filling reservoir 134.

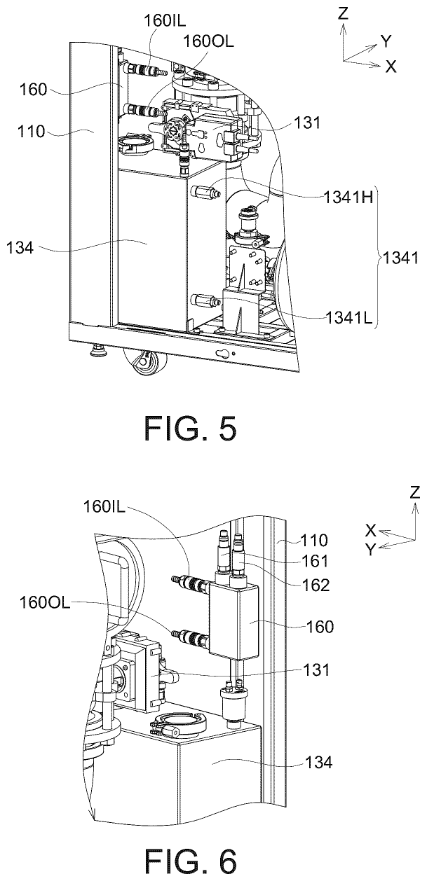

Please further refer to FIG. 6. FIG. 6 illustrates a detailed view of the liquid quality monitoring module 160 of the cooling cabinet 100 and is intended to show its configuration and operation.

The cooling cabinet 100 includes a liquid quality monitoring module 160 installed in the rack assembly 110. The liquid quality monitoring module 160 can be designed as a removable structure, allowing the user to flexibly choose whether to install the module. The liquid quality monitoring module 160 includes a pH sensor 161, a conductivity sensor 162, and a turbidity sensor 163 (shown in FIG. 2, not in FIG. 6). The pH sensor 161, conductivity sensor 162, and turbidity sensor 163 are respectively used to detect the pH value, conductivity, and turbidity of the coolant flowing through the pump modules 140. The inlet 160IL and outlet 160OL of the liquid quality monitoring module 160 are not directly connected to the main secondary loop of the coolant. Instead, a bypass pipe guides a portion of the coolant into the inlet 160IL for parameter measurement. The tested coolant is returned via the outlet 1600L to the secondary loop, completing the liquid quality monitoring process without affecting normal operation of the main loop.

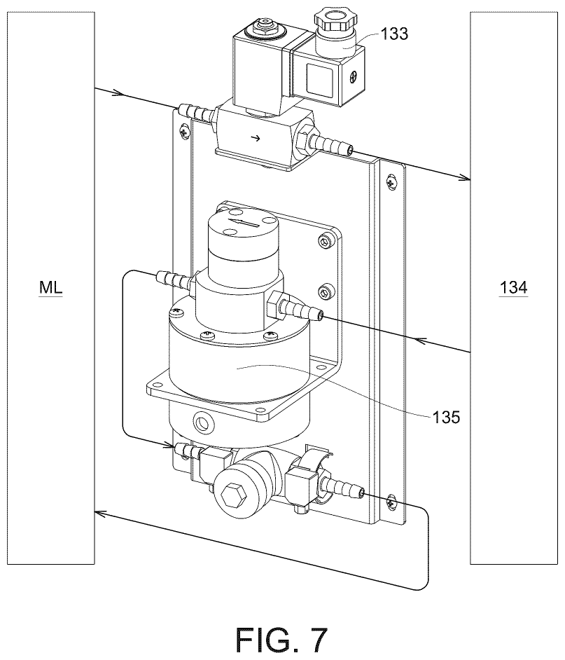

Please further refer to FIG. 7. FIG. 7 illustrates a schematic of the solenoid valve 133, the filling pump 135, a main loop ML, and the filling reservoir 134, where the main loop ML and filling reservoir 134 are represented as component blocks to indicate their function and relative positions.

As shown in FIGS. 2 and 7, a branch pipeline can be arranged along the secondary-loop supply direction in the main loop ML. This branch pipeline passes through the solenoid valve 133 to connect with the filling reservoir 134. The solenoid valve 133 enables a portion of the coolant flowing from the outlets of multiple pump modules 140 to flow into the filling reservoir 134, thereby regulating the flow rate of coolant before entering the electronic device. Through this flow diversion, system pressure relief can be achieved, further stabilizing the pressure of the coolant within the system. In addition, when the flow rate of the returning coolant in the secondary loop is insufficient, the power distribution controller 128 can control the filling pump 135 to drive the coolant from the filling reservoir 134 into the main loop ML, thereby supplementing the insufficient coolant and maintaining the stability of the return flow rate.

It will be apparent to those skilled in the art that various modifications and variations can be made to the disclosed embodiments. It is intended that the specification and examples be considered as exemplars only, with a true scope of the disclosure being indicated by the following claims and their equivalents.

What is claimed is:

1. A cooling cabinet, comprising:
a rack assembly;
a power distribution module disposed in the rack assembly;
a heat exchange module disposed in the rack assembly; and
a plurality of pump modules detachably disposed in the rack assembly, wherein each of the pump modules has an inlet and an outlet, the inlet is used to receive a coolant flowing through the heat exchange module, and each of the pump modules comprises:
a pump located adjacent to the inlet and used to drive the coolant to the outlet; and
a temperature sensor disposed downstream of the pump and located adjacent to the outlet, and being used to detect a temperature of the coolant.

2. The cooling cabinet of claim 1, wherein each of the pump modules further comprises:
an AC-DC converter electrically connected to the power distribution module and used to receive an alternating current (AC) from the power distribution module and convert the AC into a direct current (DC); and
a pump controller electrically connected to the AC-DC converter and used to receive the DC from the AC-DC converter and supply the DC to the temperature sensor.

3. The cooling cabinet of claim 2, wherein, in each of the pump modules, the temperature sensor is in communication with the pump controller to transmit a temperature signal of the coolant.

4. The cooling cabinet of claim 3, wherein the temperature signal is derived from an average temperature of at least two temperature sensors of the pump module.

5. The cooling cabinet of claim 2, wherein each of the pump modules further comprises:
a pressure sensor disposed downstream of the pump and used to detect a pressure of the coolant;
wherein the pump controller supplies the DC to the pressure sensor, and the pressure sensor is in communication with the pump controller to transmit a pressure signal of the coolant.

6. The cooling cabinet of claim 2, further comprising:
a plurality of external sensors disposed outside the pump modules, wherein each of the pump modules further includes:
a sensor hub used to receive signals from the external sensors, wherein the pump controller receives the DC from the AC-DC converter and supplies the DC to the sensor hub, and the sensor hub further supplies the DC to the external sensors;
wherein the sensor hub is in communication with the pump controller to integrate the signals from the external sensors and transmit the integrated signals to the pump controller.

7. The cooling cabinet of claim 1, wherein each of the pump modules further includes:
an inverter electrically connected to the power distribution module and used to receive the AC from the power distribution module and supply the AC to the pump.

8. The cooling cabinet of claim 7, wherein each of the pump modules further includes:
a pump controller in communication with the inverter and used to control the inverter to adjust frequency and voltage so as to change a rotational speed of the pump.

9. The cooling cabinet of claim 1, wherein the power distribution module further includes a casing, an AC input connector, at least one AC output connector, an AC-DC converter and at least one DC output connector, the power distribution module inputs AC through the AC input connector and outputs the AC through the at least one AC output connector, the power distribution module converts the AC into a DC through the AC-DC converter and outputs the DC through the DC output connector;
wherein the AC input connector is disposed on one side of the casing, and the at least one DC output connector is disposed on another side of the casing.

10. The cooling cabinet of claim 1, wherein the power distribution module includes:
a casing;
an AC input connector disposed on the casing and used to receive a main power supply from outside the cooling cabinet;
a safety protection module disposed in the casing and electrically connected to the AC input connector;
a power branch module disposed in the casing and electrically connected to the safety protection module, used to distribute an AC passing through the safety protection module into a plurality of AC power branches; and
a plurality of AC output connectors disposed on the casing and respectively electrically connected to the power branch module, used to output the AC power branches;
wherein the AC output connectors are electrically connected to the pump modules in a one-to-one manner to respectively supply the AC power branches to the pump modules.

11. The cooling cabinet of claim 10, wherein the power distribution module further comprises:
an AC-DC converter disposed in the casing and electrically connected to the safety protection module, used to receive AC power from the safety protection module and convert the AC into a DC;
a DC multi-wire terminal electrically connected to the AC-DC converter, used to receive the DC from the AC-DC converter and distribute the DC into a plurality of DC power branches; and
a power distribution controller electrically connected to the DC multi-wire terminal, used to receive one of the DC power branches;
wherein the power distribution controller is in serial communication with the pump modules, and when one of the pump modules preset as a main control node fails, the power distribution controller switches to another one of the pump modules as a new main communication node.

12. The cooling cabinet of claim 11, wherein the power distribution module further comprises:
a plurality of DC output connectors disposed on the casing and respectively connected to the DC multi-wire terminal, used to receive multiple ones of the DC power branches, wherein the DC output connectors, the AC input connector and the AC output connectors are disposed on opposite sides of the casing.

13. The cooling cabinet of claim 11, wherein the heat exchange module comprises:
a heat exchanger connected to the pump modules and used to perform heat exchange on the coolant via a heat exchange fluid; and
a proportional valve electrically connected to the power distribution controller and used to adjust a valve opening thereof so as to regulate a flow rate of the heat exchange fluid.

14. The cooling cabinet of claim 13, wherein when an average temperature value of part of the temperature sensors exceeds a threshold, the proportional valve increases the valve opening thereof to increase the flow rate of the heat exchange fluid; and when the average temperature value of part of the temperature sensors is below another threshold, the proportional valve decreases the valve opening thereof to reduce the flow rate of the heat exchange fluid.

15. The cooling cabinet of claim 11, wherein the heat exchange module comprises:
a filling reservoir disposed in the rack assembly; and
a filling pump connected to the filling reservoir and electrically connected to the power distribution controller, and used to drive the coolant in the filling reservoir when an amount of the coolant entering the pump modules is insufficient.

16. The cooling cabinet of claim 15, wherein the heat exchange module includes:
a level sensor disposed in the filling reservoir and electrically connected to the power distribution controller, used to detect a liquid level of the coolant in the filling reservoir.

17. The cooling cabinet of claim 15, wherein the heat exchange module comprises:
a solenoid valve electrically connected to the power distribution controller and used to cause part of the coolant flowing out from the outlets of the pump modules to flow toward the filling reservoir.

18. A cooling loop for supplying a coolant to an electronic device for cooling, comprising:
a secondary loop piping having a secondary-loop supply port and a secondary-loop return port, wherein the secondary-loop supply port is used to output the coolant to the electronic device, and the secondary-loop return port is used to receive the coolant from the electronic device;
a heat exchange module disposed between the secondary-loop supply port and the secondary-loop return port to conduct heat exchange between the secondary loop piping and a primary loop piping; and
a plurality of pump modules disposed between the heat exchange module and the secondary-loop supply port, the pump modules being arranged in parallel, each of the pump modules having an inlet and an outlet, the inlet being used to receive the coolant flowing through the heat exchange module, and each of the pump modules comprising:
a pump located adjacent to the inlet and used to drive the coolant to the outlet; and
a temperature sensor disposed between the pump and the outlet and used to detect a temperature of the coolant.

19. The cooling loop of claim 18, wherein each of the pump modules further includes a pump controller, the temperature sensor is in communication with the pump controller to transmit a temperature signal of the coolant, and the temperature signal is an average temperature of the temperature sensors.

20. The cooling loop of claim 19, wherein a proportional valve is disposed on the primary loop piping, and a valve of the proportional valve is controlled according to the average temperature to control a flow rate of the primary loop piping.
